(19) United States
(12) Patent Application Publication
(10) Pub. No.: US 2026/0352173 A1
(43) Pub. Date: Nov. 5, 2026

(54) SMOOTHING CIRCUIT

(71) Applicants: DENSO CORPORATION, Kariya-city (JP); NATIONAL UNIVERSITY CORPORATION HOKKAIDO UNIVERSITY, Sapporo-shi (JP)

(72) Inventors: Atsuyuki HIRUMA, Kariya-city (JP); Koji ORIKAWA, Sapporo-shi (JP); Satoshi OGASAWARA, Sapporo-shi (JP)

(73) Assignees: DENSO CORPORATION, Kariya-city (JP); NATIONAL UNIVERSITY CORPORATION HOKKAIDO UNIVERSITY, Sapporo-shi (JP)

(21) Appl. No.: 19/707,811

(22) Filed: Jun. 15, 2026

Related U.S. Application Data
(63) Continuation of application No. PCT/JP2025/003196, filed on Jan. 31, 2025.

(30) Foreign Application Priority Data
Feb. 28, 2024 (JP) 2024-029107

(51) Int. Cl. H03H 7/01

(52) U.S. Cl. CPC H03H 7/0115

(57) ABSTRACT

A smoothing circuit in the present disclosure includes a positive electrode wiring, a negative electrode wiring, and a first capacitor unit and a second capacitor unit connected in parallel between the positive electrode wiring and the negative electrode wiring. The positive electrode wiring has a positive electrode connection part connected to each of the first and second capacitor units. The negative electrode wiring has a negative electrode connection part connected to each of the first and second capacitor units. The positive electrode wiring and the negative electrode wiring cross each other three-dimensionally. An inductance of the positive electrode wiring is substantially equal to an equivalent series inductance of the first capacitor unit. An inductance of the negative electrode wiring is substantially equal to an equivalent series inductance of the second capacitor unit. The smoothing circuit includes a snubber circuit connected between the positive electrode wiring and the negative electrode wiring.

### CROSS-REFERENCE TO RELATED APPLICATION

The present application is a continuation application of International Application No. PCT/JP2025/003196, filed on Jan. 31, 2025, which claims priority to Japanese Patent Application No. 2024-029107, filed in Japan on Feb. 28, 2024. The contents of these applications are incorporated herein by reference in their entirety.

### BACKGROUND

### 1. Technical Field

The present disclosure relates to a smoothing circuit including a plurality of capacitors.

### 2. Related Art

For example, a noise filter device is disclosed which includes a positive electrode wiring, a negative electrode wiring, and a first capacitor and a second capacitor connected in parallel between the positive electrode wiring and the negative electrode wiring. The positive electrode wiring connects a first positive electrode connection part connected to the first capacitor and a second positive electrode connection part connected to the second capacitor, and the negative electrode wiring connects a first negative electrode connection part connected to the second capacitor unit and a second negative electrode connection part connected to the first capacitor. The positive electrode wiring and the negative electrode wiring form a three-dimensional crossover.

### SUMMARY

The present disclosure provides a smoothing circuit. As an aspect of the technology of the present disclosure, a smoothing circuit includes a positive electrode wiring, a negative electrode wiring, and a first capacitor unit and a second capacitor unit connected in parallel between the positive electrode wiring and the negative electrode wiring. The positive electrode wiring includes a first positive electrode connection part connected to the first capacitor unit and a second positive electrode connection part connected to the second capacitor unit. The negative electrode wiring includes a first negative electrode connection part connected to the second capacitor unit and a second negative electrode connection part connected to the first capacitor unit. The positive electrode wiring and the negative electrode wiring are arranged to cross each other three-dimensionally. An inductance of the positive electrode wiring is substantially equal to an equivalent series inductance of the first capacitor unit. An inductance of the negative electrode wiring is substantially equal to an equivalent series inductance of the second capacitor unit. The smoothing circuit further includes a snubber circuit connected between the positive electrode wiring and the negative electrode wiring.

### BRIEF DESCRIPTION OF THE DRAWINGS

In the accompanying drawings:

FIG. 1 is a circuit diagram of a smoothing circuit of a first embodiment;

FIG. 2 is a front view illustrating a structure of the smoothing circuit of the first embodiment;

FIG. 3 is a plan view of the smoothing circuit of FIG. 2;

FIG. 4 is a plan view illustrating a case of the smoothing circuit of the first embodiment;

FIG. 5 is a plan view illustrating a modification of the structure of the smoothing circuit;

FIG. 6 is a circuit diagram of a smoothing circuit of a second embodiment;

FIG. 7 is a front view illustrating a structure of the smoothing circuit of the second embodiment;

FIG. 8 is a plan view of the smoothing circuit of FIG. 7;

FIG. 9 is a graph illustrating simulation results of surge peak voltages of Comparative Examples and the second embodiment; and

FIG. 10 is a circuit diagram of a smoothing circuit of a third embodiment.

### DETAILED DESCRIPTION OF THE PREFERRED EMBODIMENTS

In a noise filter device disclosed in Japanese Unexamined Patent Application Publication No. 2022-162441 (hereinafter, referred to as JP 2022-162441 A), equalizing inductances of the positive electrode wiring are set to match the equivalent series inductances (ESLs) of the first capacitor and the second capacitor. This cancels out the ESLs of the capacitors, thereby improving noise reduction performance.

Incidentally, when the noise filter device disclosed in JP 2022-162441 A is connected between a DC power supply and a power conversion circuit, noise transmitted from the power conversion circuit, which is a noise source, to the DC power supply can be reduced. However, since the inductances of the positive electrode wiring and the negative electrode wiring are made higher in order to cancel out the ESLs of the first capacitor and the second capacitor, surge voltage applied to the power conversion circuit increases. Specifically, according to the configuration disclosed in JP 2022-162441 A in which the first capacitor and the second capacitor are cross-connected to form a three-dimensional crossover of the wirings, the inductance doubles compared to a simple parallel connection. Hence, the surge voltage applied to the power conversion circuit significantly increases, whereby it is difficult to employ the noise filter device disclosed in JP 2022-162441 A as-is, for example, for a smoothing circuit connected between the DC power supply and the power conversion circuit.

The present disclosure is made to solve the above points and has a main object of providing a smoothing circuit that can suppress increase in surge voltage while improving noise reduction performance.

A first aspect for solving the points is a smoothing circuit including:
a positive electrode wiring;
a negative electrode wiring; and
a first capacitor unit and a second capacitor unit connected in parallel between the positive electrode wiring and the negative electrode wiring, in which:
   the positive electrode wiring includes a first positive electrode connection part connected to the first capacitor unit and a second positive electrode connection part connected to the second capacitor unit;
   the negative electrode wiring includes a first negative electrode connection part connected to the second capacitor unit and a second negative electrode connection part connected to the first capacitor unit,
   the positive electrode wiring and the negative electrode wiring are arranged to cross each other three-dimensionally;
   an inductance of the positive electrode wiring is substantially equal to an equivalent series inductance of the first capacitor unit;
   an inductance of the negative electrode wiring is substantially equal to an equivalent series inductance of the second capacitor unit; and
   the smoothing circuit further includes a snubber circuit connected between the positive electrode wiring and the negative electrode wiring.

According to the above configuration, the positive electrode wiring, which has the first positive electrode connection part connected to the first capacitor unit and the second positive electrode connection part connected to the second capacitor unit, and the negative electrode wiring, which has the first negative electrode connection part connected to the second capacitor unit and the second negative electrode connection part connected to the first capacitor unit cross each other three-dimensionally. That is, the positive electrode wiring and the negative electrode wiring are arranged to cross each other three-dimensionally on a projection plane defined to be perpendicular to a predetermined first direction. In addition, an inductance of the positive electrode wiring is substantially equal to an equivalent series inductance of the first capacitor unit, and an inductance of the negative electrode wiring is substantially equal to an equivalent series inductance of the second capacitor unit. Hence, the equivalent series inductances of the first capacitor unit and the second capacitor unit (hereinafter, referred to as “ESLs”) can be canceled out by the inductances of the positive electrode wiring and the negative electrode wiring, respectively, whereby noise reduction performance of the smoothing circuit can be improved.

Furthermore, since the smoothing circuit includes the snubber circuit, which is connected between the positive electrode wiring and the negative electrode wiring, an increase in surge voltage applied between the positive electrode wiring and the negative electrode wiring can be suppressed. Accordingly, the aforementioned smoothing circuit, in which the first capacitor unit and the second capacitor unit are connected in a crossed manner so that the positive electrode wiring and the negative electrode wiring cross each other three-dimensionally, can be employed, for example, as a smoothing circuit connected between a DC power supply and a power conversion circuit.

The above-mentioned and other objects, features and advantages of the present disclosure will become more apparent by reference to the following detailed description taken in conjunction with the accompanying drawings.

### First Embodiment

Hereinafter, a first embodiment embodied in a smoothing circuit connected between a DC power supply and a power conversion circuit (inverter) will be described with reference to the drawings.

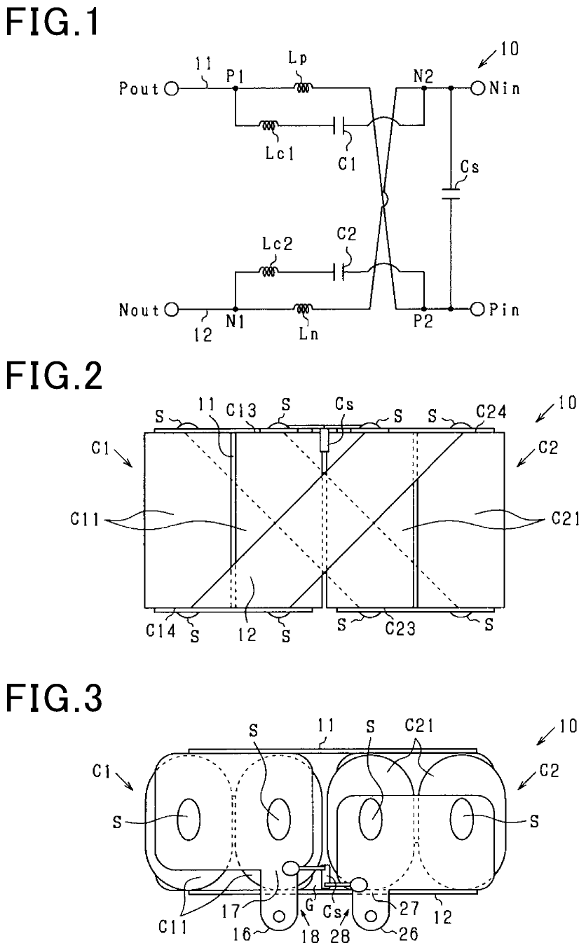

As illustrated in FIG. 1, a smoothing circuit 10 includes a positive electrode wiring 11, a negative electrode wiring 12, a first capacitor unit C1, a second capacitor unit C2, and a capacitor Cs.

The first capacitor unit C1 and the second capacitor unit C2 are connected in parallel between the positive electrode wiring 11 and the negative electrode wiring 12. The first capacitor unit C1 is configured, for example, to include two capacitors C11 connected in parallel (refer to FIGS. 2 and 3). The second capacitor unit C2 is configured, for example, to include two capacitors C21 connected in parallel (refer to FIGS. 2 and 3).

The positive electrode wiring 11 has a first positive electrode connection part P1 connected to the first capacitor unit C1 and a second positive electrode connection part P2 connected to the second capacitor unit C2. The negative electrode wiring 12 has a first negative electrode connection part N1 connected to the second capacitor unit C2 and a second negative electrode connection part N2 connected to the first capacitor unit C1. In addition, the positive electrode wiring 11 and the negative electrode wiring 12 are arranged to cross each other three-dimensionally. The structure for achieving a three-dimensional crossover will be described later.

Parasitic inductances of the first capacitor unit C1 and the second capacitor unit C2 are respectively denoted by equivalent series inductances Lc1 and Lc2. In addition, an inductance component of the positive electrode wiring 11 between the first positive electrode connection part P1 and the second positive electrode connection part P2 (inductance component of the positive electrode wiring 11) is denoted by an equivalent series inductance Lp. An inductance component of the negative electrode wiring 12 between the first negative electrode connection part N1 and the second negative electrode connection part N2 (inductance component of the negative electrode wiring 12) is denoted by an equivalent series inductance Ln. The inductance Lp is adjusted to be equal to (substantially equal to) the inductance Lc1. The inductance Ln is adjusted to be equal to (substantially equal to) the inductance Lc2. It is noted that the inductance Lp needs to be substantially equal to the inductance Lc1 within a small tolerance. The inductance Ln needs to be substantially equal to the inductance Lc2 within a small tolerance.

An input terminal Pin on the positive electrode side and an input terminal Nin on the negative electrode side are connected to switching elements (not shown) of a power conversion circuit, which is a noise source. An output terminal Pout on the positive electrode side and an output terminal Nout on the negative electrode side are connected to a DC power supply (not shown). A capacitor Cs (C snubber circuit, snubber circuit) is connected between a portion of the positive electrode wiring 11 between the second positive electrode connection part P2 and the input terminal Pin on the positive electrode side, and a portion of the negative electrode wiring 12 between the second negative electrode connection part N2 and the input terminal Nin on the negative electrode side.

Herein, Cs is a capacitance of the capacitor Cs, Lp is an inductance of the positive electrode wiring 11, I is a current that is flowing through the positive electrode wiring 11 when the switching elements are turned off, and Vb is an allowable value of surge voltage. The allowable value Vb has been set to, for example, a value lower than withstand voltages of the switching elements of the power conversion circuit by a predetermined voltage. In this case, if electrostatic energy (½·Cs·Vb\hat{ }2) that can be stored in the capacitance Cs is made higher than electromagnetic energy (½·Lp·I\hat{ }2) that has been stored in the inductance Lp of the positive electrode wiring 11, the surge voltage can be lower than the allowable value Vb. Note that “b\hat{ }2” represents the square of b. In the present embodiment, the following inequality (1) can be satisfied so that the surge voltage becomes lower than the allowable value Vb.

(½·Cs·Vb\hat{ }2)>(½·Lp·I\hat{ }2) (1)

By transforming the inequality (1), the following inequality (2) can be derived.

Cs>Lp(I/Vb)\hat{ }2 (2)

In the present embodiment, the capacitance of the capacitor Cs is set so as to satisfy the inequality (2).

As illustrated in FIGS. 2 and 3, the capacitors C11 and C21 are formed into elongated cylindrical (cylindrical) shapes. The axial directions of the capacitors C11 and C21 (vertical direction in FIG. 2) are the longitudinal directions of the capacitors C11 and C21. The arrangement direction of the capacitor units C1 and C2 (horizontal directions in FIGS. 2 and 3) is the longitudinal direction of the smoothing circuit 10.

The positive electrode wiring 11 and the negative electrode wiring 12 are arranged to cross each other three-dimensionally, with the first capacitor unit C1 and the second capacitor unit C2 being interposed therebetween. That is, the positive electrode wiring 11 and the negative electrode wiring 12 are arranged to cross each other on a projection plane projected in the direction (predetermined first direction) perpendicular to the arrangement direction of the capacitor units C1 and C2 (the longitudinal direction of the smoothing circuit 10, the horizontal directions in FIGS. 2 and 3) and the axial directions of the capacitors C11 and C21 (the longitudinal directions of the capacitors C11 and C21, the vertical direction in FIG. 2). Outer peripheral surfaces of the capacitors C11 and C21 are insulated from the positive electrode wiring 11 and the negative electrode wiring 12.

The first capacitor unit C1 has a positive electrode C13 (first electrode) and a negative electrode C14 (second electrode). The second capacitor unit C2 has a positive electrode C23 (first electrode) and a negative electrode C24 (second electrode). The first capacitor unit C1 and the second capacitor unit C2 are disposed so that the orientations of the positive electrodes of the respective first capacitor unit C1 and second capacitor unit C2 are opposite to each other in the vertical direction (predetermined direction) and the orientations of the negative electrodes of the respective first capacitor unit C1 and second capacitor unit C2 are opposite to each other in the vertical direction. For example, in the first capacitor unit C1, the positive electrode C13 is disposed on the upper side, and the negative electrode C14 is disposed on the lower side, whereas in the second capacitor unit C2, the positive electrode C23 is disposed on the lower side, and the negative electrode C24 is disposed on the upper side. The positive electrodes C13 and C23 of the capacitor units C1 and C2 (capacitors C11 and C21) and the positive electrode wiring 11 are connected via solders S. The negative electrodes C14 and C24 of the capacitor units C1 and C2 (capacitors C11 and C21) and the negative electrode wiring 12 are connected via solders S.

The positive electrode wiring 11 connects the positive electrode C13 of the first capacitor unit C1 and the positive electrode C23 of the second capacitor unit C2 diagonally with respect to the vertical direction in FIG. 2 (the axial directions of the capacitors C11 and C21, the predetermined direction). The negative electrode wiring 12 connects the negative electrode C14 of the first capacitor unit C1 and the negative electrode C24 of the second capacitor unit C2 diagonally with respect to the vertical direction in FIG. 2 (the axial directions of the capacitors C11 and C21, the predetermined direction).

The positive electrode wiring 11 and the negative electrode wiring 12 are formed of, for example, bus bars, which are plates made of copper (metal). Adjusting lengths, widths, and thicknesses of the bus bars can control inductance components of the positive electrode wiring 11 and the negative electrode wiring 12. Hence, the inductance Lp of the positive electrode wiring 11 is made equal (substantially equal) to an equivalent series inductance Lc1 of the first capacitor unit C1. The inductance Ln of the negative electrode wiring 12 is made equal (substantially equal) to an equivalent series inductance Lc2 of the second capacitor unit C2.

As illustrated in FIG. 3, a gap G is formed between the first capacitor unit C1 and the second capacitor unit C2. The gap G is formed between the outer peripheral surface of the elongated cylindrical capacitor C11 and the outer peripheral surface of the elongated cylindrical capacitor C21, and extends in the axial directions (longitudinal directions) of the capacitors C11 and C21. The capacitor Cs (snubber circuit) is disposed in the gap G.

The smoothing circuit 10 includes a positive electrode terminal 16 connected to the positive electrode wiring 11 and a negative electrode terminal 26 connected to the negative electrode wiring 12. The positive electrode terminal 16 and the negative electrode terminal 26 are disposed side-by-side, and extend in the direction (the predetermined first direction) perpendicular to the axial directions (longitudinal directions) of the capacitors C11 and C21 and the longitudinal direction of the smoothing circuit 10 (the direction in which the capacitors C11 and C21 are arranged).

The smoothing circuit 10 includes a positive electrode terminal unit 18 at the positive electrode wiring 11 which includes the positive electrode terminal 16 and a connection part 17 connected with the positive electrode terminal 16, and a negative electrode terminal unit 28 at the negative electrode wiring 12 which includes the negative electrode terminal 26 and a connection part 27 connected with the negative electrode terminal 26. The capacitor Cs is connected between the positive electrode terminal unit 18 and the negative electrode terminal unit 28. Specifically, the capacitor Cs is connected between the connection part 17 and the connection part 27.

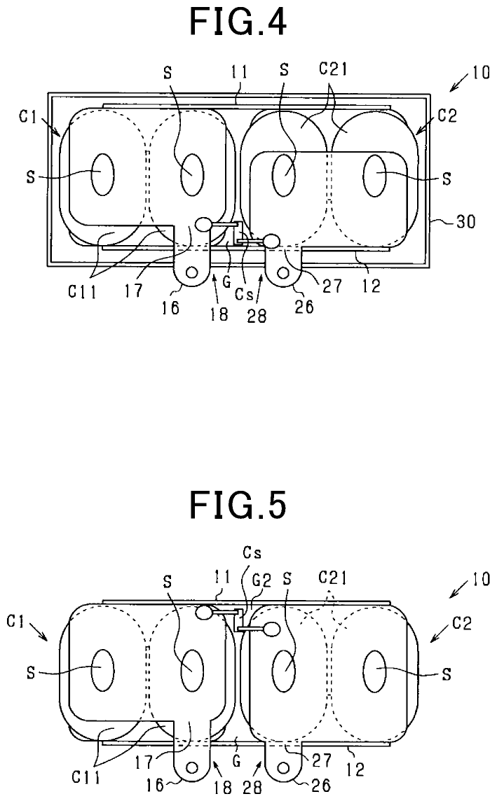

As illustrated in FIG. 4, the positive electrode wiring 11, the positive electrode wiring 12, the first capacitor unit C1, the second capacitor unit C2, and the capacitor Cs are accommodated in a case 30. The case 30 is formed, for example, of an insulating material and into a bottomed rectangular cylindrical shape (hollow box shape) and has a lid (not shown). After the positive electrode wiring 11, the negative electrode wiring 12, the first capacitor unit C1, the second capacitor unit C2, and the capacitor Cs are accommodated in the case 30, for example, an epoxy resin (insulating resin) is charged into the case 30, and the lid of the case 30 is closed. Hence, the smoothing circuit 10 is configured as a smoothing circuit module (capacitor module).

The present embodiment described above in detail has the following advantageous effects.

The positive electrode wiring 11, which has the first positive electrode connection part P1 connected to the first capacitor unit C1 and the second positive electrode connection part P2 connected to the second capacitor unit C2, and the negative electrode wiring 12, which has the first negative electrode connection part N1 connected to the second capacitor unit C2 and the second negative electrode connection part N2 connected to the first capacitor unit C1, cross each other three-dimensionally. In addition, the inductance Lp of the positive electrode wiring 11 is substantially equal to the equivalent series inductance Lc1 of the first capacitor unit C1, and the inductance Ln of the negative electrode wiring 12 is substantially equal to the equivalent series inductance Lc2 of the second capacitor unit C2. Hence, the equivalent series inductances Lc1 and Lc2 of the first capacitor unit C1 and the second capacitor unit C2 (hereinafter, referred to as “ESLs”) can be canceled out by the inductances Lp and Ln of the positive electrode wiring 11 and the negative electrode wiring 12, respectively, whereby noise reduction performance of the smoothing circuit 10 can be improved.

Since the smoothing circuit 10 includes the capacitor Cs, which is a C snubber circuit, connected between the positive electrode wiring 11 and the negative electrode wiring 12, an increase in surge voltage applied between the positive electrode wiring 11 and the negative electrode wiring 12 can be suppressed. Hence, the smoothing circuit 10, in which the first capacitor unit C1 and the second capacitor unit C2 are connected in a crossed manner so that the positive electrode wiring 11 and the negative electrode wiring 12 cross each other three-dimensionally, can be employed as a smoothing circuit connected between the DC power supply and the power conversion circuit.

Since the first capacitor unit C1 and the second capacitor unit C2 are disposed side-by-side in the direction perpendicular to the predetermined direction, the first capacitor unit C1 and the second capacitor unit C2 can be easily disposed together in one location. Furthermore, since the capacitor Cs is disposed in the gap G between the first capacitor unit C1 and the second capacitor unit C2, the smoothing circuit 10, including the capacitor Cs, can be easily miniaturized.

Since the positive electrode terminal 16 and the negative electrode terminal 26 are disposed side-by-side, the distance between the positive electrode terminal 16 and the negative electrode terminal 26 can be shortened. Furthermore, the capacitor Cs is connected between the positive electrode terminal unit 18 and the negative electrode terminal unit 28. Hence, the length of the wiring from the connection part 17 connected with the positive electrode terminal unit 18 at the positive electrode wiring 11 to the positive electrode terminal 16 can be shortened. Similarly, the length of the wiring from the connection part 27 connected with the negative electrode terminal unit 28 at the negative electrode wiring 12 to the negative electrode terminal 26 can be shortened. Hence, inductance of the wiring from the positive electrode terminal 16 to the capacitor Cs can be decreased. Similarly, inductance of the wiring from the negative electrode terminal 26 to the capacitor Cs can be decreased. As a result, surge voltage applied between the positive electrode terminal 16 and the negative electrode terminal 26 can be lowered.

The capacitance Cs of the capacitor Cs, which is a C snubber circuit, the inductance Lp of the positive electrode wiring 11, the current I flowing through the positive electrode wiring 11, and the allowable value Vb of surge voltage satisfy Cs>Lp(I/Vb)\hat{ }2. According to the configuration, the electrostatic energy (½·Cs·Vb\hat{ }2) that can be stored in the capacitance Cs can be higher than the electromagnetic energy (½·Lp·I\hat{ }2) that has been stored in the inductance Lp of the positive electrode wiring 11. Hence, the surge voltage applied between the positive electrode wiring 11 and the negative electrode wiring 12 can be lower than the allowable value Vb.

The smoothing circuit 10 includes the case 30 that accommodates the positive electrode wiring 11, the negative electrode wiring 12, the first capacitor unit C1, the second capacitor unit C2, and the capacitor Cs therein. According to the configuration, the smoothing circuit 10 can be modularized by accommodating the positive electrode wiring 11, the negative electrode wiring 12, the first capacitor unit C1, the second capacitor unit C2, and the capacitor Cs in the case 30. Hence, the smoothing circuit 10 can be handled easily.

The first capacitor unit C1 and the second capacitor unit C2 are disposed so that the orientations of the positive electrodes of the respective first capacitor unit C1 and second capacitor unit C2 are opposite to each other in the predetermined direction and the orientations of the negative electrodes of the respective first capacitor unit C1 and second capacitor unit C2 are opposite to each other in the predetermined direction. The positive electrode wiring 11 connects the positive electrode C13 of the first capacitor unit C1 and the positive electrode C23 of the second capacitor unit C2 diagonally with respect to the predetermined direction. The negative electrode wiring 12 connects the negative electrode C14 of the first capacitor unit C1 and the negative electrode C24 of the second capacitor unit C2 diagonally with respect to the predetermined direction. According to the arrangement, the configuration in which the positive electrode wiring 11 and the negative electrode wiring 12 cross each other three-dimensionally can be achieved using a shorter positive electrode wiring 11 and a shorter negative electrode wiring 12.

The positive electrode wiring 11 and the negative electrode wiring 12 are arranged to cross each other three-dimensionally, with the first capacitor unit C1 and the second capacitor unit C2 being interposed therebetween. According to the configuration, when the positive electrode wiring 11 and the negative electrode wiring 12 are caused to cross each other three-dimensionally, the positive electrode wiring 11 and the negative electrode wiring 12 can be easily arranged.

It is noted that the above embodiment may also be implemented with the following modifications. For the same parts as those in the above embodiment, the same reference numerals are assigned, whereby the descriptions thereof are incorporated by reference.

A capacitor Cs that does not satisfy Cs>Lp(I/Vb)\hat{ }2 may also be employed. Also in this case, compared with the configuration that does not include the capacitor Cs (C snubber circuit, snubber circuit), increase in surge voltage applied between the positive electrode wiring 11 and the negative electrode wiring 12 can be suppressed.

As illustrated in FIG. 5, the negative electrode wiring 12 may be extended in a direction opposite to the direction in which the negative electrode terminal 26 extends (upper direction in FIG. 5), and the capacitor Cs may be connected between an end of the positive electrode wiring 11 opposite to the positive electrode terminal 16 and an end of the negative electrode wiring 12 opposite to the negative electrode terminal 26. In addition, the capacitor Cs (snubber circuit) may also be disposed in a gap G2 between the first capacitor unit C1 and the second capacitor unit C2 on the side opposite to the positive electrode terminal 16 and the negative electrode terminal 26.

### Second Embodiment

Hereinafter, a second embodiment will be described focusing on differences from the first embodiment. It is noted that, for the same parts as those in the first embodiment, the same reference numerals are assigned, whereby the descriptions thereof are incorporated by reference.

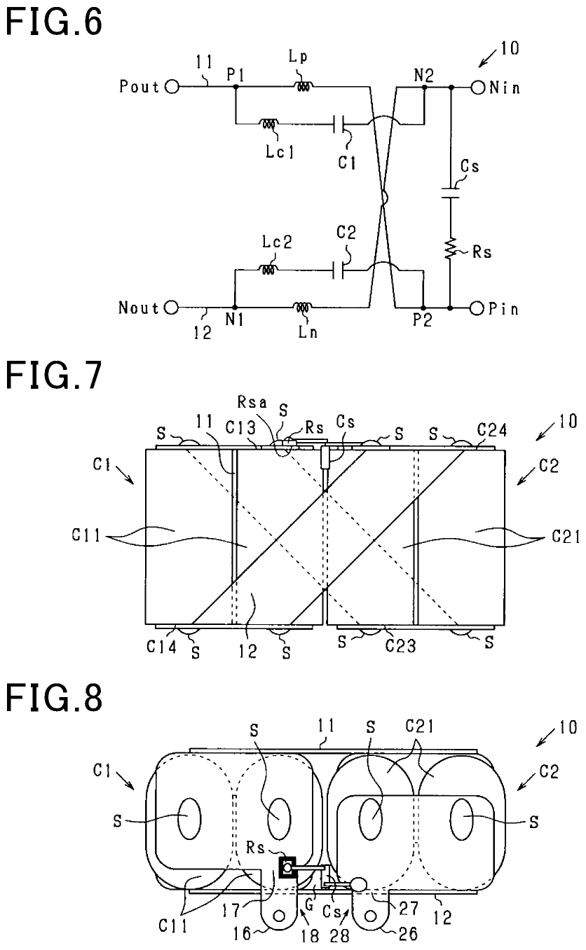

As illustrated in FIG. 6, in the present embodiment, the smoothing circuit 10 includes an RC snubber circuit (snubber circuit) configured by a resistor Rs and the capacitor Cs. The resistor Rs and the capacitor Cs are connected in series between a portion of the positive electrode wiring 11 between the second positive electrode connection part P2 and the input terminal Pin on the positive electrode side and a portion of the negative electrode wiring 12 between the second negative electrode connection part N2 and the input terminal Nin on the negative electrode side.

As illustrated in FIGS. 7 and 8, the capacitor Cs is disposed in the gap G. The resistor Rs and the capacitor Cs are connected between the positive electrode terminal unit 18 and the negative electrode terminal unit 28. The resistor Rs is formed into a plate shape. A largest surface Rsa of the resistor Rs is in close contact with the positive electrode wiring 11 (bus bar).

According to the above configuration, the largest surface Rsa of the resistor Rs is in close contact with the positive electrode wiring 11 formed of a bus bar. Hence, the bus bar can function as a heat sink that dissipates heat from the resistor Rs, thereby preventing the resistor Rs from overheating. In addition, the present embodiment can also provide the effects according to the first embodiment.

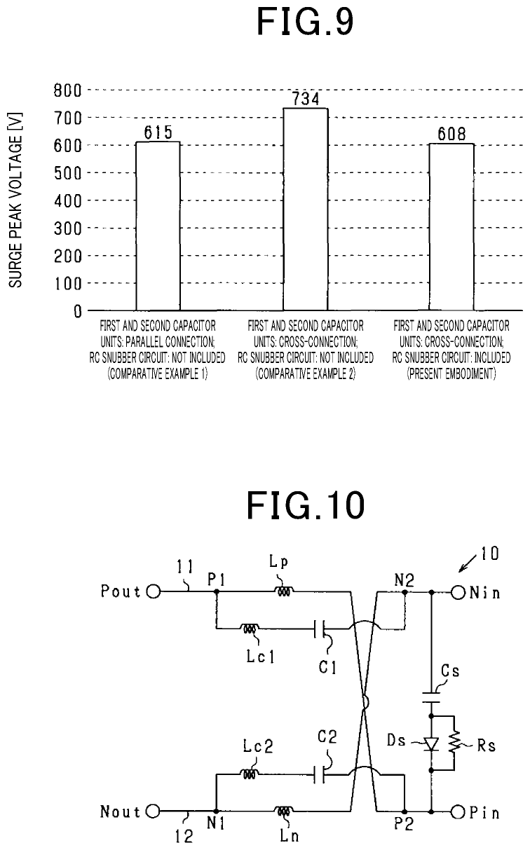

FIG. 9 is a graph illustrating simulation results of surge peak voltages of Comparative Examples and the present embodiment.

In a configuration of Comparative Example 1, the first capacitor unit C1 (two capacitors C11) and the second capacitor unit C2 (two capacitors C21) are connected simply in parallel between the positive electrode wiring 11 and the negative electrode wiring 12, and no snubber circuit is included. In this case, the peak of surge voltage is 615 [V].

In a configuration of Comparative Example 2, the first capacitor unit C1 and the second capacitor unit C2 are cross-connected, and no snubber circuit is included. In this case, the peak of surge voltage is 734 [V]. Since inductances of the positive electrode wiring 11 and the negative electrode wiring 12 have been made higher in order to cancel out ESLs of the first capacitor unit C1 and the second capacitor unit C2, the surge voltage has increased. Specifically, since the first capacitor unit C1 and the second capacitor unit C2 are cross-connected such that the positive electrode wiring 11 and the negative electrode wiring 12 form a three-dimensional crossover, the inductances have doubled, and the surge voltage has increased compared with Comparative Example 1.

The present embodiment has the configuration in which the first capacitor unit C1 and the second capacitor unit C2 are connected in a crossed manner, and the RC snubber circuit configured by the resistor Rs and the capacitor Cs is included. In this case, the peak of surge voltage is 608 [V]. That is, the RC snubber circuit can suppress increase in surge voltage applied between the positive electrode wiring 11 and the negative electrode wiring 12.

It is noted that a configuration may be employed in which the largest surface Rsa of the resistor Rs is not in close contact with the positive electrode wiring 11 formed of a bus bar. In addition, a configuration may be employed in which the entire resistor Rs is not in close contact with the positive electrode wiring 11 formed of a bus bar.

### Third Embodiment

Hereinafter, a third embodiment will be described focusing on differences from the first embodiment. It is noted that, for the same parts as those in the first embodiment, the same reference numerals are assigned, whereby the descriptions thereof are incorporated by reference.

As illustrated in FIG. 10, in the present embodiment, the smoothing circuit 10 includes an RCD snubber circuit (snubber circuit) configured by the resistor Rs, the capacitor Cs, and a diode Ds. The resistor Rs and the diode Ds are connected in parallel with the capacitor Cs. The RCD snubber circuit is connected between a portion of the positive electrode wiring 11 between the second positive electrode connection part P2 and the input terminal Pin on the positive electrode side and a portion of the negative electrode wiring 12 between the second negative electrode connection part N2 and the input terminal Nin on the negative electrode side. According to the configuration, the RCD snubber circuit can suppress an increase in surge voltage applied between the positive electrode wiring 11 and the negative electrode wiring 12. In addition, the present embodiment can also provide the advantageous effects according to the first embodiment and the second embodiment.

It is noted that the above first to third embodiments may also be implemented with the following modifications. For the same parts as those in the first to third embodiments, the same reference numerals are assigned, whereby the descriptions thereof are incorporated by reference.

A configuration may be employed in which the capacitor Cs is disposed in a place other than the gaps G and G2 between the first capacitor unit C1 and the second capacitor unit C2.

The bus bars forming the positive electrode wiring 11 and the negative electrode wiring 12 may be, for example, bars made of copper (made of metal). This case can also provide the advantageous effects according to the first to the third embodiments and the modifications thereof.

A configuration may be employed in which the smoothing circuit 10 does not include the case 30, that is, the smoothing circuit 10 is not modularized.

The positive electrode wiring 11 and the negative electrode wiring 12 may cross each other three-dimensionally, without the first capacitor unit C1 and the second capacitor unit C2 being interposed therebetween.

The first capacitor unit C1 may be configured to include one capacitor C11 or three or more capacitors C11. The second capacitor unit C2 may be configured to include one capacitor C21 or three or more capacitors C21.

The smoothing circuits 10 of the first to third embodiments and the modifications thereof can be applied to a smoothing circuit connected between a DC charger and a battery.

It is noted that the above embodiments and modifications can also be implemented in any technically possible combination.

Hereinafter, characteristic configurations indicated in the embodiments and the modifications above will be described.

### Configuration 1

A smoothing circuit including:
a positive electrode wiring;
a negative electrode wiring; and
a first capacitor unit and a second capacitor unit connected in parallel between the positive electrode wiring and the negative electrode wiring, in which:
   the positive electrode wiring includes a first positive electrode connection part connected to the first capacitor unit and a second positive electrode connection part connected to the second capacitor unit;
   the negative electrode wiring includes a first negative electrode connection part connected to the second capacitor unit and a second negative electrode connection part connected to the first capacitor unit;
   the positive electrode wiring and the negative electrode wiring are arranged to cross each other three-dimensionally;
   an inductance of the positive electrode wiring is substantially equal to an equivalent series inductance of the first capacitor unit;
   an inductance of the negative electrode wiring is substantially equal to an equivalent series inductance of the second capacitor unit; and
   the smoothing circuit further includes a snubber circuit connected between the positive electrode wiring and the negative electrode wiring.

### Configuration 2

The smoothing circuit according to Configuration 1, in which:
the first capacitor unit and the second capacitor unit are disposed side-by-side, and
the snubber circuit is disposed in a gap between the first capacitor unit and the second capacitor unit.

### Configuration 3

The smoothing circuit according to Configuration 1 or 2, further including:
a positive electrode terminal that is connected to the positive electrode wiring; and
a negative electrode terminal that is connected to the negative electrode wiring and is disposed side-by-side with the positive electrode terminal, in which
the snubber circuit is connected between a positive electrode terminal unit at the positive electrode wiring, which includes the positive electrode terminal and a connection part connected with the positive electrode terminal, and a negative electrode terminal unit at the negative electrode wiring, which includes the negative electrode terminal and a connection part connected with the negative electrode terminal.

### Configuration 4

The smoothing circuit according to any one of Configurations 1 to 3, in which:
the snubber circuit includes a capacitor and a resistor having a plate shape;
the positive electrode wiring and the negative electrode wiring are formed of bus bars, which are plates or bars made of conductors; and
a largest surface of the resistor is in close contact with the positive electrode wiring or the negative electrode wiring.

### Configuration 5

The smoothing circuit according to any one of Configurations 1 to 4, in which:
the snubber circuit includes a capacitor, and
a capacitance Cs of the capacitor, an inductance Lp of the positive electrode wiring, a current I that is flowing through the positive electrode wiring, and an allowable value Vb of surge voltage satisfy Cs>Lp(I/Vb)\hat{ }2.

### Configuration 6

The smoothing circuit according to any one of Configurations 1 to 5, further including
a case that accommodates the positive electrode wiring, the negative electrode wiring, the first capacitor unit, the second capacitor unit, and the snubber circuit therein.

### Configuration 7

The smoothing circuit according to any one of Configurations 1 to 6, in which:
the first capacitor unit has a first electrode and a second electrode;
the second capacitor unit has a first electrode and a second electrode;
the first capacitor unit and the second capacitor unit are disposed so that orientations of the first electrodes of the respective first capacitor unit and second capacitor unit are opposite to each other in a predetermined direction, and orientations of the second electrodes of the respective first capacitor unit and second capacitor unit are opposite to each other in the predetermined direction;
the first capacitor unit and the second capacitor unit are disposed side-by-side in a direction perpendicular to the predetermined direction;
the positive electrode wiring connects the first electrode of the first capacitor unit and the first electrode of the second capacitor unit diagonally with respect to the predetermined direction; and
the negative electrode wiring connects the second electrode of the first capacitor unit and the second electrode of the second capacitor unit diagonally with respect to the predetermined direction.

### Configuration 8

The smoothing circuit according to Configuration 7, in which:
the positive electrode wiring and the negative electrode wiring cross each other three-dimensionally, with the first capacitor unit and the second capacitor unit being interposed therebetween.

Although the present disclosure has been described in accordance with embodiments, it is understood that the present disclosure is not limited to such embodiments or structures. The present disclosure encompasses various modifications and variations within the scope of equivalents. In addition, various combinations and forms, as well as other combinations and forms including only one element, more than one element, or less than one element, are within the concept and scope of the present disclosure.

What is claimed is:

1. A smoothing circuit comprising:
a positive electrode wiring;
a negative electrode wiring; and
a first capacitor unit and a second capacitor unit connected in parallel between the positive electrode wiring and the negative electrode wiring, wherein:
the positive electrode wiring includes a first positive electrode connection part connected to the first capacitor unit and a second positive electrode connection part connected to the second capacitor unit;
the negative electrode wiring includes a first negative electrode connection part connected to the second capacitor unit and a second negative electrode connection part connected to the first capacitor unit;
the positive electrode wiring and the negative electrode wiring are arranged to cross each other three-dimensionally;
an inductance of the positive electrode wiring is substantially equal to an equivalent series inductance of the first capacitor unit;
an inductance of the negative electrode wiring is substantially equal to an equivalent series inductance of the second capacitor unit; and
the smoothing circuit further comprises a snubber circuit connected between the positive electrode wiring and the negative electrode wiring.

2. The smoothing circuit according to claim 1, wherein:
the first capacitor unit and the second capacitor unit are disposed side-by-side, and
the snubber circuit is disposed in a gap between the first capacitor unit and the second capacitor unit.

3. The smoothing circuit according to claim 1, further comprising:
a positive electrode terminal that is connected to the positive electrode wiring; and
a negative electrode terminal that is connected to the negative electrode wiring and is disposed side-by-side with the positive electrode terminal, wherein
the snubber circuit is connected between a positive electrode terminal unit at the positive electrode wiring, which includes the positive electrode terminal and a connection part connected with the positive electrode terminal, and a negative electrode terminal unit at the negative electrode wiring, which includes the negative electrode terminal and a connection part connected with the negative electrode terminal.

4. The smoothing circuit according to claim 1, wherein
the snubber circuit includes a capacitor and a resistor having a plate shape;
the positive electrode wiring and the negative electrode wiring are formed of bus bars, which are plates or bars made of conductors; and
a largest surface of the resistor is in close contact with the positive electrode wiring or the negative electrode wiring.

5. The smoothing circuit according to claim 1, wherein
the snubber circuit includes a capacitor, and
a capacitance Cs of the capacitor, an inductance Lp of the positive electrode wiring, a current I that is flowing through the positive electrode wiring, and an allowable value Vb of surge voltage satisfy Cs>Lp(I/Vb)\hat{ }2.

6. The smoothing circuit according to claim 1, further comprising
a case that accommodates the positive electrode wiring, the negative electrode wiring, the first capacitor unit, the second capacitor unit, and the snubber circuit therein.

7. The smoothing circuit according to claim 1, wherein:
the first capacitor unit has a first electrode and a second electrode;
the second capacitor unit has a first electrode and a second electrode;
the first capacitor unit and the second capacitor unit are disposed so that orientations of the first electrodes of the respective first capacitor unit and second capacitor unit are opposite to each other in a predetermined direction and orientations of the second electrodes of the respective first capacitor unit and second capacitor unit are opposite to each other in the predetermined direction;
the first capacitor unit and the second capacitor unit are disposed side-by-side in a direction perpendicular to the predetermined direction;
the positive electrode wiring connects the first electrode of the first capacitor unit and the first electrode of the second capacitor unit diagonally with respect to the predetermined direction; and
the negative electrode wiring connects the second electrode of the first capacitor unit and the second electrode of the second capacitor unit diagonally with respect to the predetermined direction.

8. The smoothing circuit according to claim 7, wherein
the positive electrode wiring and the negative electrode wiring cross each other three-dimensionally, with the first capacitor unit and the second capacitor unit being interposed therebetween.
